(19) United States
(12) Patent Application Publication
(10) Pub. No.: US 2008/0037206 A1
(43) Pub. Date: Feb. 14, 2008

(54) Hinge assembly for display

(75) Inventor: Chien-Cheng Huang, Sinjhuang City (TW)

Correspondence Address: Rosenberg, Klein & Lee;Suite 101, 3458 Ellicott Center Drive, Ellicott City, MD, 21043, US

(73) Assignee: Lite-On Technology Corporation

(21) Appl. No.: 11/705,775

(22) Filed: Feb. 14, 2007

(30) Foreign Application Priority Data
Aug. 8, 2006 (TW) 95213938

(51) Int. Cl. H05K 7/16

(52) U.S. Cl. 361/681

(57) ABSTRACT

A hinge assembly includes two connecting bases, a rotating element, two sets of washers, and two locking elements. The connecting base includes a base part and a first ear part. The first ear part has a first shaft hole and a concave opening. The rotating element includes a linking part and two second ear parts. The second ear part has a second shaft hole and a blocking protrusion. The rotating element straddles and is located on two connecting bases. The two blocking protrusions respectively place into two concave openings. The two sets of washers are located on a side of the first ear parts and the two second ear parts. The locking elements insert within the first shaft holes of the two connecting bases, the second shaft holes of the rotating element, and the two sets of washers. Thereby, the two connecting bases are pivoted with the rotating element.

### BACKGROUND OF THE INVENTION

1. Field of the Invention

The present invention relates to a hinge assembly. In particular, it is applied to the display device of each electronic apparatus, such as an LCD, and is used for supporting and adjusting the angle of the display panel.

2. Description of the Related Art

Because LCDs are thin, light, and small, and consume a small amount of power, LCDs are widely applied to information apparatus. In order to allow a user to view the display at the best possible viewing angle, there is a hinge assembly between the display panel and the base of the LCD. The hinge assembly can support the LCD and allows the viewing angle to be adjusted.

FIG. 1 shows a hinge assembly of the prior art. The hinge assembly 9 includes a connecting base 91, a bottom board 92, a rotating element 93, and two locking elements 94. The connecting base 91 is a U-shaped board. The bottom of the connecting base 91 is connected with the bottom board 92 via a plurality of screws. Therefore, the connecting base 91 utilizes the bottom board 92 to connect to the base of the LCD. Ear parts 911 and 931 extend from two sides of the connecting base 91 and the rotating element 93 respectively. The two locking elements 94 insert within the two ear parts 911 of the connecting base 91 respectively, the two ear parts 931 of the rotating element 93 and a plurality of washers 95, and are fastened to the locking element 94 via the nuts 96. Therefore, the connecting base 91 is pivoted to the rotating element 93. The display panel of the LCD is connected to the rotating element 93 so that the display panel is pivoted to the base via the hinge,assembly 9. Thereby, the display panel can be adjusted forwards and backwards.

However, the hinge assembly of the prior art needs a bottom board 92 to be installed in the bottom of the connecting base 91, and a plurality of screws are required to connect the connecting base 91 and the bottom board 92. The structure is complex, the quantity of required elements is large, and the cost of the materials is high. Besides, the assembling tolerance is large, and the yield rate is low.

Further, R.O.C. patent M289010 discloses a supporting apparatus for a display. The supporting apparatus includes a body and two supporting frames. The body has two ear parts. Each of the ear parts has a through hole. The side wall of at least one of the through holes has a thread. Each of the supporting frames has a fastening shaft. On an outside surface of at least one fastening shaft, there is a thread corresponding to the thread of the side wall of the through hole. The fastening shafts insert within the through holes respectively. The supporting apparatus for a display further includes a plurality of washers and board-shaped springs. The washers and the board-shaped springs are respectively located at the fastening shafts. Two sides of the board-shaped springs respectively lean against the washers and the ear parts.

The structure of the mentioned prior art also involves in the problems of complex design, high material cost, large assembling tolerance and low yield rate.

### SUMMARY OF THE INVENTION

One particular aspect of the present invention is to provide a hinge assembly to lower the cost of material and simplify the structure. The manufacturing process becomes easily, the assembling tolerance is lowered, the yield rate is enhanced, and its structural strength is unchanged. It also has a good performance.

In order to achieve the above purpose, the present invention provides a hinge assembly, comprising: two connecting bases each including a base part, and a first ear part vertically extending from one side of the base part, wherein the first ear part having a first shaft hole and a concave opening; a rotating element including a linking part, and two second ear parts vertically extending from two sides of the linking part, wherein the two second ear parts respectively having a second shaft hole and a blocking protrusion, wherein the rotating element straddles and is located on two connecting bases, and the two blocking protrusions respectively placing into the two concave openings; two sets of washers each including a plurality of washers, wherein the washers are configured between the first ear parts of the two connecting bases and the two second ear parts of the rotating element respectively; and two locking elements inserting within the first shaft holes of the two connecting bases, the second shaft holes of the rotating element, and the washers of the two sets of washers, so as to pivot the two connecting bases and the rotating element with each other.

The present invention integrates and modulizes the required elements to reduce the cost of material and simplify its structure. The manufacturing process becomes easily, and its structural strength is unchanged. It also has a good performance.

For further understanding of the invention, reference is made to the following detailed description illustrating the embodiments and examples of the invention. The description is only for illustrating the invention and is not intended to be considered limiting of the scope of the claim.

### BRIEF DESCRIPTION OF THE DRAWINGS

The drawings included herein provide a further understanding of the invention. A brief introduction of the drawings is as follows:

FIG. 1 is a perspective view of the hinge assembly of the prior art;

FIG. 2 is an exploded perspective view of the hinge assembly of the present invention;

FIG. 3 is a perspective view of the hinge assembly of the present invention;

FIG.,4 is another perspective view of the hinge assembly of the present invention;

FIG. 5 is a top view of the hinge assembly of the present invention;

FIG. 6 is a side view of the hinge assembly of the present invention; and

FIG. 7 is a schematic diagram of the hinge assembly of the present invention installed to an LCD.

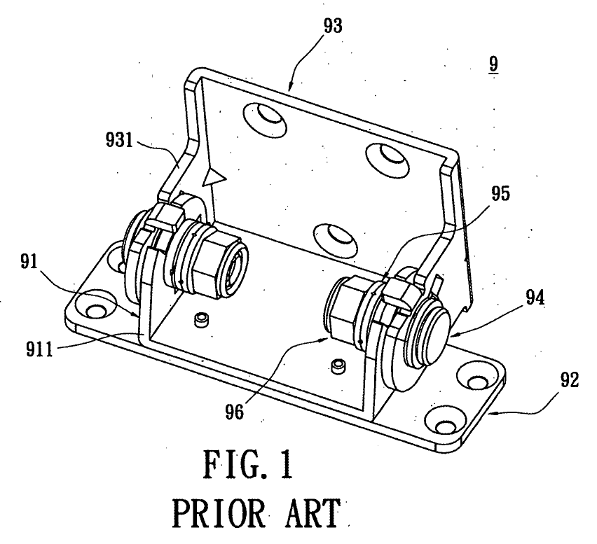

### DETAILED DESCRIPTION OF THE PREFERRED EMBODIMENTS

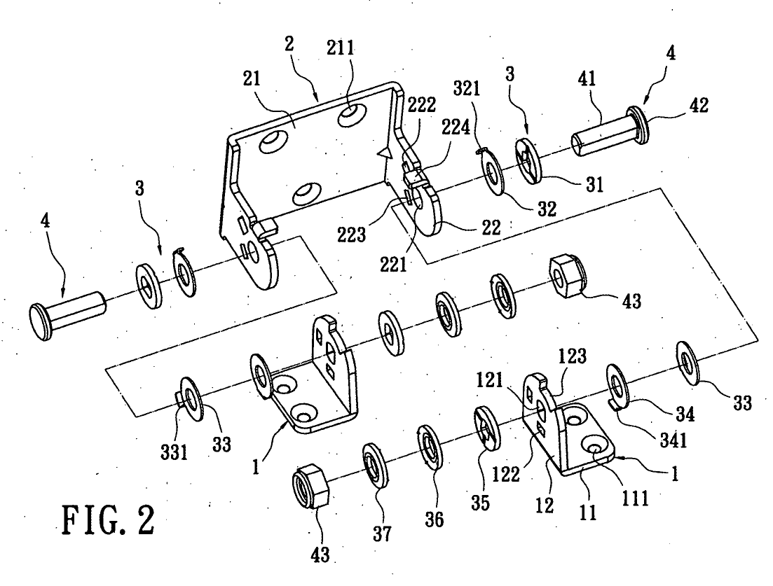

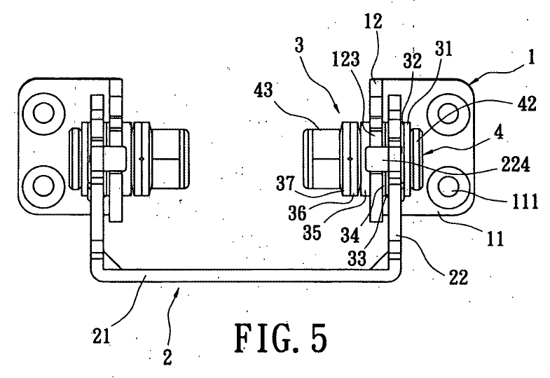

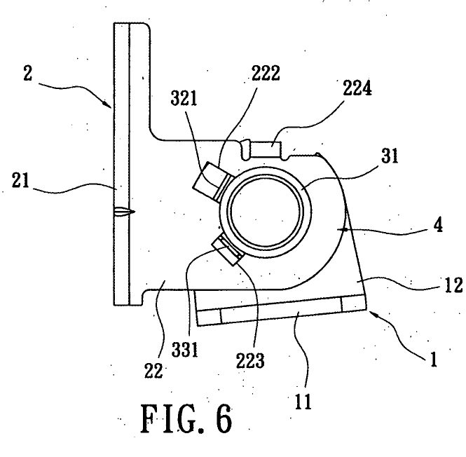

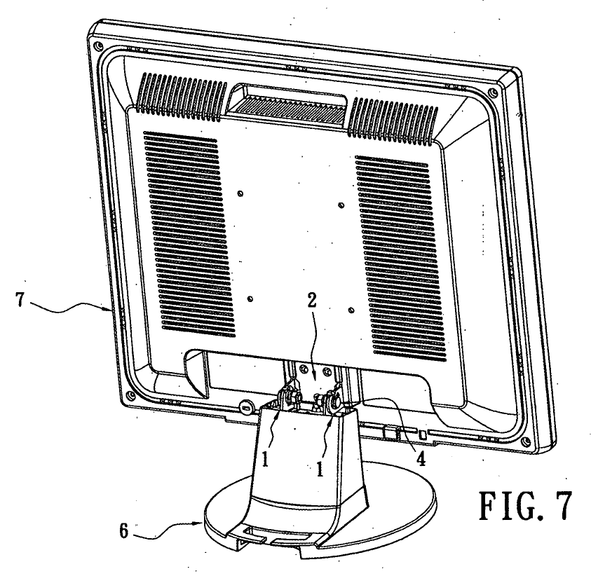

Reference is made to FIGS. 2-6. The hinge assembly includes two connecting bases 1, a rotating element 2, two sets of washers 3, and two locking elements 4. The two connecting bases 1 are made of metal boards. Each of the connecting bases 1 includes a base part 11 and a first ear part 12 vertically extending from one side of the base part 11, such as a board in form of L-shaped or LL-shaped (i.e. two parallel ear parts). On the base part 11, there are two connecting holes 111. The base part 11 is screwed on the base 6 of an LCD (as shown in FIG. 7) by the screws. The first ear part 12 has a non-circular first shaft hole 121. At outside area of the first shaft hole 121, there is a second through hole 122. At an edge of the first ear part 12, there is a concave opening 123. The concave opening 123 formed a similar U-shape establishes an opening angle with a specific angle. Preferably, 5 degreed forwards to 30 degreed backwards for the best mode of the present invention. Specifically, the two ends of the concave opening 123 are formed blocking points.

The rotating element 2 is made of metal board and which includes a linking part 21, and two second ear parts 22 vertically extending from two sides of the linking part 21. The rotating element 2 is a U-shaped board. On the linking part 21, there are three connecting holes 211. The linking part 21 is screwed on a LCD panel 7 (as shown in FIG. 7) by the screws. Each of the two second ear parts 22 has a circular second shaft hole 221. On the outside area of the second shaft hole 221, there are a first through hole 222 and a third through hole 223. On an edge of the each second ear part 22, a blocking protrusion 224 extends inward into the inside of the rotating element 2. The blocking protrusion 224 protrudes to the inner wall of the second ear part 22. The rotating element 2 straddles and is located on the two connecting bases 1. The two second ear parts 22 of the rotating element 2 are respectively located on an outside of each first ear parts 12 of the two connecting bases 1. The two blocking protrusions 224 of the rotating element 2 insert within the two concave openings 123 of the connecting bases 1 respectively. Thereby, each of the two blocking protrusions 224 is stopped by one of the two ends of the concave openings 123 to provide with a position-limiting capability for controlling the related rotating angle between the rotating element 2 and the two connecting bases 1. Alternatively, the two second ear parts 22 of the rotating element 2 can be located on an inner side of the first ear parts 12 of the two connecting bases 1 respectively. Thus, each two blocking protrusions 224 would be formed directionally from the edge of the second ear part 22 to the first ear part 12, and which inserts within the concave opening 123 of each two connecting bases 1.

Each set of washers 3 includes a first washer 31, a second washer 32, a third washer 33, a fourth washer 34, a fifth washer 35, a sixth washer 36 and a seventh washer 37. The first washer 31 and the second washer 32 are located on an outside of the second ear part 22 of the rotating element 2. A protruding part 321 extends from an edge of the second washer 32 and which plugs into the first through hole 222 of the second ear part 22. The third washer 33 and the fourth washer 34 are located between an inner side of the second ear part 22 of the rotating element 2 and an outside of the first ear part 12 of the connecting base 1. In this embodiment, each two second ear parts 22 of the rotating element 2 is respectively located on an outside of each first ear parts 12 of the two connecting bases 1. In addition, a protruding part 331 extends from an edge of the third washer 33 and plugs into the third through hole 223 of the second ear part 22. Also, a protruding part 341 extends from an edge of the fourth washer 34 and plugs into the second through hole 122 of the first ear part 12. The fifth washer 35, the sixth washer 36, and the seventh washer 37 are located on an inner side of the first ear part 12 of the connecting base 1.

Each of the two locking elements 4 (bolts or pins, for example) has a shaft part 41 and a head part 42 connected to one end of the shaft part 41. The shaft part 41 is a non-circular shaft body preferably. The outside diameter of the head part 42 is larger than that of the shaft part 41. The shaft part 41 of each two locking elements 4 inserts within the first washer 31, the second washer 32, the second shaft hole 221 of the rotating element 2, the third washer 33, the fourth washer 34, the first shaft hole 121 of the connecting base 1, the fifth washer 35, the sixth washer 36 and the seventh washer 37 sequentially, and then connected to a fastening element 43 (such as a nut). The fastening element 43 fastens the locking element 4 so that the two connecting bases 1 and the rotating element 2 are pivoted together. The friction force, produced the rotation between the locking element 4 and those washers, provides the suitable damping effect to adjust the related rotating angle between the rotating element 2 and the two connecting bases 1.

Reference is made to FIG. 7. The hinge assembly of the present invention can be configured between the base 6 of the LCD and the display panel 7 in order to support the display panel and adjust the viewing angle of the LCD display panel. Accordingly, the two locking elements 4 could be utilized as a fulcrum for the related rotation between the display panel 7, the rotating element 2 and the base 6, the connecting base 1. Thereby, the inclination angle of the display panel 5 for viewing can be adjusted.

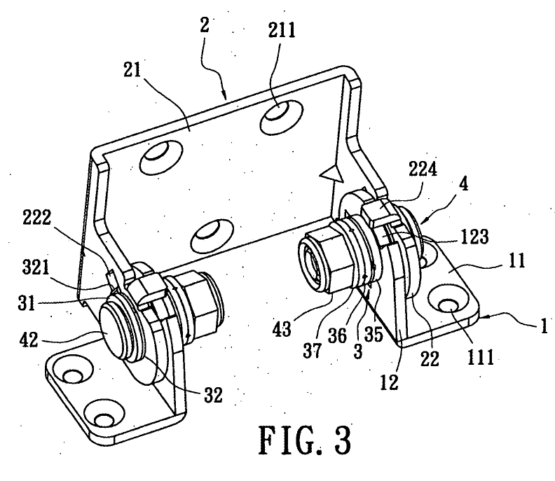

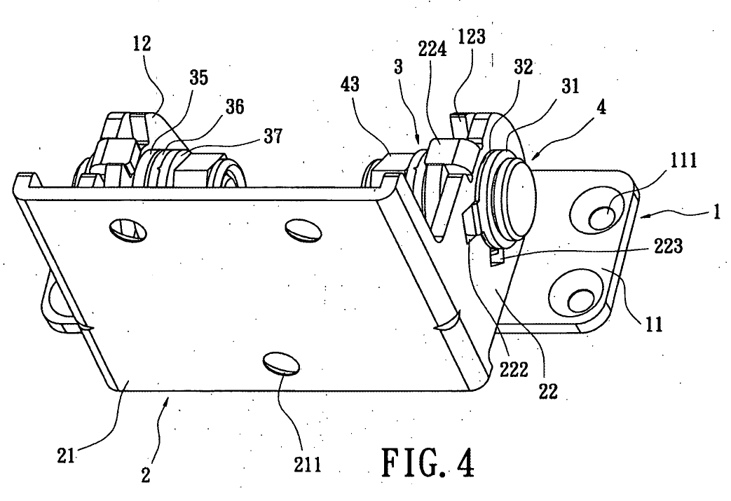

Furthermore, as shown in FIGS. 3-6, since the rotation of the rotating element 2 and the connecting base 1 is allowable, and the effectiveness of the two ends of the concave opening 123 for providing the position-limit to the blocking protrusion 224 is achieved. Thereby, the display panel 7 is adjusted forwards and backwards to a proper angle and is positioned. The inclination angle of the display panel 7 is determined by the established angle of the concave opening 123.

The present invention integrates and modulizes the required elements. The two connecting bases 1 can be directly connected with the base 6 of the LCD without a bottom board as prior art. Therefore, the cost of material is lowered and its structure is simplified. The manufacturing and assembling process are easy, and its structural strength is maintained. It also has a good performance.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. A hinge assembly, comprising:
two connecting bases each including a base part, and a first ear part vertically extending from one side of the base part, wherein the first ear part having a first shaft hole and a concave opening;
a rotating element including a linking part, and two second ear parts vertically extending from two sides of the linking part, wherein the two second ear parts respectively having a second shaft hole and a blocking protrusion, wherein the rotating element straddles and is located on two connecting bases, and the two blocking protrusions respectively placing into the two concave openings;
two sets of washers each including a plurality of washers, wherein the washers are configured between the first ear parts of the two connecting bases and the two second ear parts of the rotating element respectively; and
two locking elements inserting within the first shaft holes of the two connecting bases, the second shaft holes of the rotating elements, and the washers of the two sets of washers, so as to pivot the two connecting bases and the rotating element with each other.

2. The hinge assembly as claimed in claim 1, wherein the base parts of the two connecting bases further have at least one connecting hole respectively for connecting a base.

3. The hinge assembly as claimed in claim 1, wherein the linking part of the rotating element further has at least one connecting hole for connecting a display panel.

4. The hinge assembly as claimed in claim 1, wherein the two second ear parts are respectively located at an outside or an inner side of the two first ear parts.

5. The hinge assembly as claimed in claim 1, wherein the two sets of washers each include a first washer and a second washer located at an outside of the second ear part of the rotating element, wherein a protruding part extends from the second washer, the outside area of the second shaft hole has a first through hole, and the protruding part of the second washer plugging into the first through hole.

6. The hinge assembly as claimed in claim 5, wherein the two sets of washers each also include a third washer and a fourth washer located between the second ear part of the rotating element and the first ear part of the connecting base, wherein a protruding part respectively extends from the third washer and the fourth washer, the outside areas of the first shaft hole and the second shaft hole have a second through hole and a third through hole respectively, the protruding part of the third washer plugs into the third through hole, and the protruding part of the fourth washer plugs into the second through hole.

7. The hinge assembly as claimed in claim 6, wherein the two sets of washers each further include a fifth washer, a sixth washer and a seventh washer located on an inside of the first ear part of the connection base.

8. The hinge assembly as claimed in claim 7, wherein each of the two locking elements has a shaft part and a head part connected to one end of the shaft part, wherein the shaft parts of the two locking elements inserting within the washers of the two sets of washers, the second shaft holes of the rotating element, and the first shaft holes of the connecting bases, and which are connected with a fastening element respectively.

9. The hinge assembly as claimed in claim 8, wherein the locking elements are such as bolts and the fastening element is such as a nut.

10. A display device for LCD monitor, comprising:
a base;
a panel; and
a hinge assembly, comprising:
two connecting bases each including a base part, and a first ear part vertically extending from one side of the base part, wherein the first ear part having a first shaft hole and a concave opening;
a rotating element including a linking part, and two second ear parts vertically extending from two sides of the linking part, wherein the two second ear parts respectively having a second shaft hole and a blocking protrusion, wherein the rotating element straddles and is located on two connecting bases, and the two blocking protrusions respectively placing into the two concave openings;
two sets of washers each including a plurality of washers, wherein the washers are configured between the first ear parts of the two connecting bases and the two second ear parts of the rotating element respectively; and
two locking elements inserting within the first shaft holes of the two connecting bases, the second shaft holes of the rotating elements, and the washers of the two sets of washers, so as to pivot the two connecting bases and the rotating element with each other;
wherein the panel is fastened to the base via the hinge assembly.

11. The display device for LCD monitor as claimed in claim 10, wherein the base parts of the two connecting bases further have at least one connecting hole respectively for connecting the base.

12. The display device for LCD monitor as claimed in claim 10, wherein the linking part of the rotating element further has at least one connecting hole for connecting the display panel.

13. The display device for LCD monitor as claimed in claim 10, wherein the two second ear parts are respectively located at an outside, or an inner side of the two first ear parts.

14. The display device for LCD monitor as claimed in claim 10, wherein the two sets of washers each include a first washer and a second washer located at an outside of the second ear part of the rotating element, wherein a protruding part extends from the second washer, the outside area of the second shaft hole has a first through hole, and the protruding part of the second washer plugging into the first through hole.

15. The display device for LCD monitor as claimed in claim 14, wherein the two sets of washers each also include a third washer and a fourth washer located between the second ear part of the rotating element and the first ear part of the connecting base, wherein a protruding part respectively extends from the third washer and the fourth washer, the outside areas of the first shaft hole and the second shaft hole have a second through hole and a third through hole respectively, the protruding part of the third washer plugs into the third through hole, and the protruding park of the fourth washer plugs into the second through hole.

16. The display device for LCD monitor as claimed in claim 15, wherein the two sets of washers each further include a fifth washer, a sixth washer and a seventh washer located on an inside of the first ear part of the connection base.

17. The display device for LCD monitor as claimed in claim 16, wherein each of the two locking elements has a shaft part and a head part connected to one end of the shaft part, wherein the shaft parts of the two locking elements inserting within the washers of the two sets of washers, the second shaft holes of the rotating element, and the first shaft holes of the connecting bases, and which are connected with a fastening element respectively.

18. The display device for LCD monitor as claimed in claim 17, wherein the locking elements are such as bolts and the fastening element is such as a nut.
